(19) United States
(12) Patent Application Publication
(10) Pub. No.: US 2026/0283009 A1
(43) Pub. Date: Sep. 17, 2026

(54) INTEGRATED CIRCUIT (IC) PACKAGE HAVING A PACKAGE MOLD LAYER AND A STIFFENER IN THE PACKAGE MOLD LAYER TO REDUCE WARPAGE

(71) Applicant: QUALCOMM Incorporated, San Diego, CA (US)

(72) Inventors: Pavan Rajmane, Escondido, CA (US); Abhishek Nitin Deshpande, San Diego, CA (US); Aniket Patil, San Diego, CA (US); Manuel Aldrete, Encinitas, CA (US)

(21) Appl. No.: 19/079,786

(22) Filed: Mar. 14, 2025

(51) Int. Cl. H01L 23/24; H01L 21/56; H01L 23/00; H01L 23/31; H01L 25/16

(52) U.S. Cl. CPC H10W 76/47; H10W 74/016; H10W 90/00; H10W 42/121; H10W 74/117; H10W 90/724

(57) ABSTRACT

Aspects disclosed include an integrated circuit (IC) package having a package mold layer and a stiffener in the package mold layer to reduce warpage. The IC package includes a die coupled to a substrate. The package mold layer encapsulates the die. To strengthen an IC package, the IC package disclosed herein deploys a stiffener in the package mold layer.

### TECHNICAL FIELD

The field of the disclosure relates to design and manufacturing of integrated circuit (IC) packages.

### BACKGROUND

Integrated circuits (ICs) are the cornerstone of electronic devices. ICs are packaged in an IC package, also called a “semiconductor package” or “chip package.” The IC package includes one or more semiconductor dice (“dies” or “dice”) as an IC(s) that are mounted on and electrically coupled to a package substrate to provide physical support and an electrical interface to the die(s). The die(s) may be a system on chip which includes multiple processors and various special processors including a graphics processor (GPU), modem processors, and the like. The die may also be an individual processor or modem die. The die(s) is electrically interfaced to metal interconnects (e.g., metal traces) exposed in a top layer of the package substrate. The package substrate also includes one or more metallization layers that include metal interconnects (e.g., metal traces, metal lines) with vertical interconnect accesses (vias) coupling the metal interconnects together between adjacent metallization layers to provide electrical interfaces between the die(s). The package substrate also includes a bottom, outer metallization layer that includes metal interconnects coupled to external metal interconnects (e.g., ball grid array (BGA) interconnects, land grid array (LGA)) to provide an external interface between the die(s) in the IC package. The die(s) may be mounted to the top layer of the package substrate through die interconnects. Other dies may also be mounted, utilizing die interconnects, to the bottom, outer metallization layer that includes metal interconnects between BGA interconnects.

### SUMMARY

Aspects disclosed in the detailed description include an integrated circuit (IC) package having a package mold layer and a stiffener in the package mold layer to reduce warpage. IC package height requirements decrease due to device manufacturers creating devices that require smaller and smaller profiles. For example, phone manufacturers that deploy processor dies in an eyeglass form-factor require that a modem deployed in the eyeglass form-factor be smaller than the processor dies deployed in a phone. To strengthen an IC package, the IC package disclosed herein deploys a stiffener in the package mold layer. Another approach to addressing warpage would include selecting substrate and package mold materials whose coefficient of thermal expansion (CTE) would match the CTE of a die in the IC package. However, there are no known materials that exactly match a die's CTE and the materials that come within a few parts per million of a die's CTE are prohibitively expensive. By utilizing the stiffener in the mold, the IC package is strengthened without increasing the height profile of the IC package at a reasonable cost.

In this regard in one aspect, an IC package is disclosed. The IC package comprises a die comprising a plurality of die interconnects and a substrate having a top surface and extending in a horizontal direction, the plurality of die interconnects coupled to the top surface of the substrate. The IC package further comprises a package mold layer extending in the horizontal direction and encapsulating the die and a stiffener disposed in the package mold layer.

In another aspect, a method of fabricating an IC package is disclosed. The method of fabricating an IC package comprises forming a die comprising a plurality of die interconnects extending in a vertical direction and forming a substrate having a top surface and extending in a horizontal direction, the plurality of die interconnects coupled to the top surface of the substrate. The method of fabricating an IC package further comprises forming a package mold layer extending in the horizontal direction and encapsulating the die and forming a stiffener disposed in the package mold layer.

### BRIEF DESCRIPTION OF THE DRAWINGS

FIG. 1 is a side view of an exemplary integrated circuit (IC) package that includes a package mold layer and a stiffener in the package mold layer to reduce warpage;

FIG. 2 is a side view of another exemplary IC package that includes a package mold layer and a stiffener in the package mold layer to reduce warpage;

FIG. 3 is a side view of another exemplary IC package that includes a package mold layer and a stiffener in the package mold layer to reduce warpage;

FIG. 4 is a side view of another exemplary IC package that includes a package mold layer and a stiffener in the package mold layer to reduce warpage;

FIG. 5A is a top view of an exemplary stiffener having a hollow quadrangle shape including, but not limited to, the stiffeners illustrated in FIGS. 1-4;

FIG. 5B is a top view of another exemplary stiffener having a rectangular grid shape including, but not limited to, the stiffeners illustrated in FIGS. 1-4;

FIG. 5C is a top view of another exemplary stiffener having a quadrangle with two cross members, each cross member attached to opposing corners of the quadrangle, the stiffener including, but not limited to, the stiffeners illustrated in FIGS. 1-4;

FIG. 6 is a flowchart illustrating an exemplary fabrication process of fabricating an IC package including, but not limited to, the IC packages described in FIGS. 1-4, wherein the IC package includes a package mold layer and a stiffener in the package mold layer to reduce warpage;

FIG. 7 is a flowchart illustrating an exemplary fabrication process of a die module including, but not limited to, the die module in the IC packages described in FIGS. 1-4, wherein the die module will be fabricated in an IC package including a package mold layer and a stiffener in the package mold layer to reduce warpage;

FIGS. 8A-8C are exemplary fabrication stages during fabrication of the die module according to the fabrication process in FIG. 7;

FIGS. 9A-9B is a flowchart illustrating an exemplary fabrication process of fabricating an IC package including, but not limited to, the IC packages described in FIGS. 1-4, wherein the IC package includes a package mold and a stiffener in the package mold layer to reduce warpage;

FIGS. 10A-10E are exemplary fabrication stages during fabrication of the IC package according to the fabrication process in FIGS. 9A-9B;

FIG. 11 is a block diagram of an exemplary processor-based system that can include an IC package including a package mold layer and a stiffener in the package mold layer to reduce warpage, including, but not limited to, the IC packages in FIGS. 1-4, and fabricated according to the fabrication processes in FIGS. 6, 7, and 9A-9B; and

FIG. 12 is a block diagram of an exemplary wireless communications device that includes radio-frequency (RF) components that can include an IC package including a package mold layer and a stiffener in the package mold layer to reduce warpage, including, but not limited to, the IC packages in FIGS. 1-4, and fabricated according to the fabrication processes in FIGS. 6, 7, and 9A-9B.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

It should be understood that the terms “first,” “second,” “third,” etc., where used herein, are relative terms that may be used to distinguish between similarly named elements and are not meant to limit or imply a strict orientation and/or order unless otherwise specified. It should also be understood that that the terms “top,” “upper,” “above,” and “bottom,” “lower,” “below,” where used herein, are relative terms and are not meant to limit or imply a strict orientation. A “top” or “upper” or “above” referenced element does not always need to be oriented to be above a “bottom,” or “lower,” or “below” referenced element with respect to ground, and vice versa. An element referenced as “top,” “upper,” “above,” or “bottom,” “lower,” “below,” may be on top or bottom relative to that example only and the particular illustrated example. An element referenced as “top” or “upper” or “above” “bottom,” “lower,” “below,” another element does not have to be with respect to ground, and vice versa. An element referenced as “top” or “upper” or “above” may be above or below such other referenced element, relative to that example only and the particular illustrated example. For example, if a particular object that is discussed as at “top,” or “upper” or “above” another object, and such particular object is flipped 180 degrees, then such particular object would then be oriented as at “bottom,” or “lower” or “below” such other object.

Further, an object being “adjacent” as discussed herein relates to an object being beside or next to another stated object. Adjacent objects may not be directly physically coupled to each other. An object can be directly adjacent to another object which means that such objects are directly beside or next to the other object without another object or layer being intervening or disposed between the directly adjacent objects. An object can be indirectly or non-directly adjacent to another object which means that such objects are not directly beside or directly next to each other, but there is an intervening object or layer disposed between the non-directly adjacent objects.

Aspects disclosed in the detailed description include an integrated circuit (IC) package having a package mold layer and a stiffener in the package mold layer to reduce warpage. IC package height requirements decrease due to device manufacturers creating devices that require smaller and smaller profiles. For example, phone manufacturers that deploy processor dies in an eyeglass form-factor require that a modem deployed in the eyeglass form-factor be smaller than the processor dies deployed in a phone. To strengthen an IC package, the IC package disclosed herein deploys a stiffener in the package mold layer. Another approach to addressing warpage would include selecting substrate and package mold materials whose coefficient of thermal expansion (CTE) would match the CTE of a die in the IC package. However, there are no known materials that exactly match a die's CTE and the materials that come within a few parts per million of a die's CTE are prohibitively expensive. By utilizing the stiffener in the mold, the IC package is strengthened without increasing the height profile of the IC package at a reasonable cost.

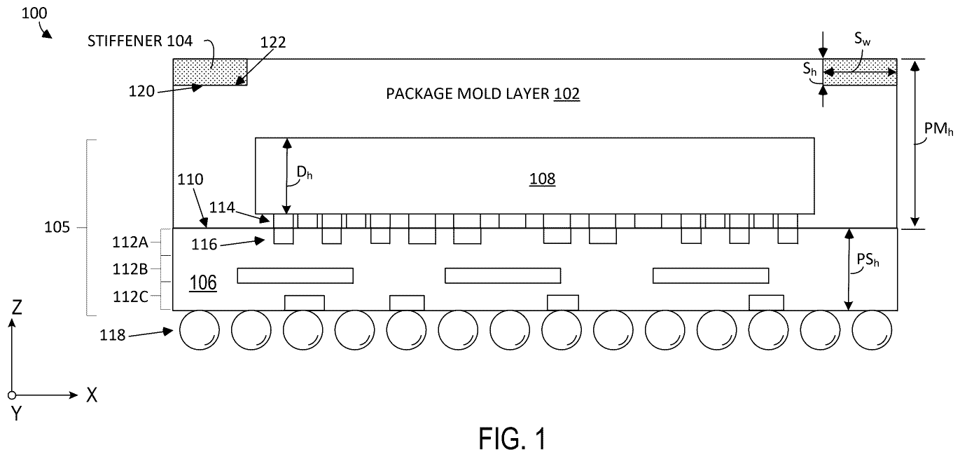

In this regard, FIG. 1 is a side view of an exemplary integrated circuit (IC) package 100 that includes a package mold layer 102 and a stiffener 104 in the package mold layer 102 to reduce warpage. The IC package 100 includes a die module 105. The die module 105 includes a substrate 106 extending in a horizontal direction (X-, Y-axes direction) and a die 108 coupled to a top surface 110 of the substrate 106, in a vertical direction (Z-axis direction), of the substrate 106. The substrate 106 commonly routes signals and power between the die 108 and the substrate 106 and a printed circuit board (PCB) (not shown). The die 108 has a height approximately 400 micrometers (μm).

In this example, the substrate 106 includes metallization layers 112A-112C including a first, upper metallization layer 112A and a bottom, outer metallization layer 112C. The substrate 106 includes the top surface 110. The die 108 includes die interconnects 114 (e.g., raised metal bumps, pillars) extending in the vertical direction (Z-axis direction) that are electrically coupled to metal interconnects including metal pads 116 in the first, upper metallization layer 112A. The die interconnects 114 are suitable for carrying signals between the die 108 and the substrate 106. The substrate 106 has a height PSₕ between 100-500 μm.

The IC package 100 includes an array of solder balls 118 which are suitable for coupling the IC package 100 to a PCB (not shown). The metallization layers 112A-112C are suitable for carrying signals between the die 108 through the die interconnects 114 to the solder balls 118.

The package mold layer 102 extends in the horizontal direction (X-, Y-axes direction) and encapsulates the die 108. The package mold layer 102 has a height PMₕ in the vertical direction (Z-axis direction) which is approximately 900 μm. The coefficients of thermal expansion (CTEs) of the die 108, the substrate 106, and the package mold layer 102 are not equal. For example, the die 108 has a CTE, CTE_{d}, which may be close to 3. The substrate 106 has a CTE, CTEₚₛ, which may be in a range between 12-16 parts per million (ppm). The package mold layer 102 has a CTE, CTEₚₘ, which may be close to 40 ppm.

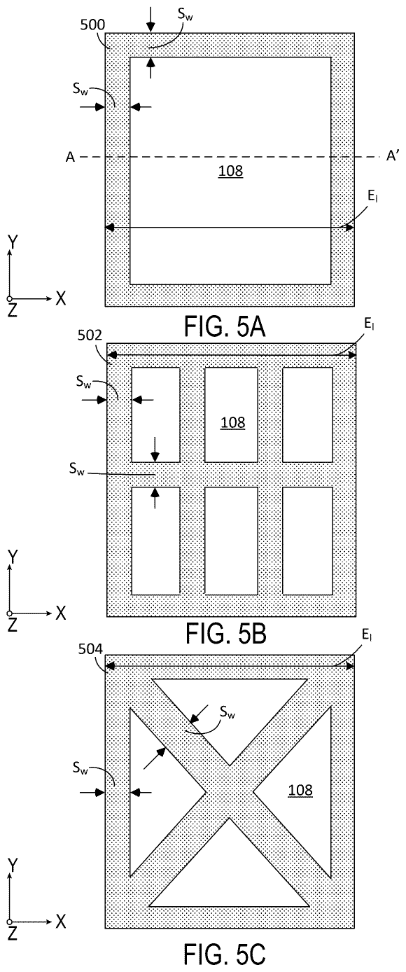

The package mold layer 102 includes a package mold surface 120 which extends around the periphery of the substrate 106 as can be seen in FIG. 5A. The stiffener 104 has a bottom surface 122. The stiffener 104 is directly adjacent to the package mold surface 120. In other words, the bottom surface 122 is coincident with the package mold surface 120. The stiffener 104 has a height Sₕ of approximately 100 μm but can be in the range between 100-200 μm. The stiffener 104 has a width S_{w} of approximately 500 μm but can be in the range between 500-1000 μm. Thus, the stiffener 104 has a ratio of width to height of 5 but can be in the range between 2.5-10. The stiffener 104 has a shape from a top view perspective of a hollow quadrangle as shown in FIG. 5A.

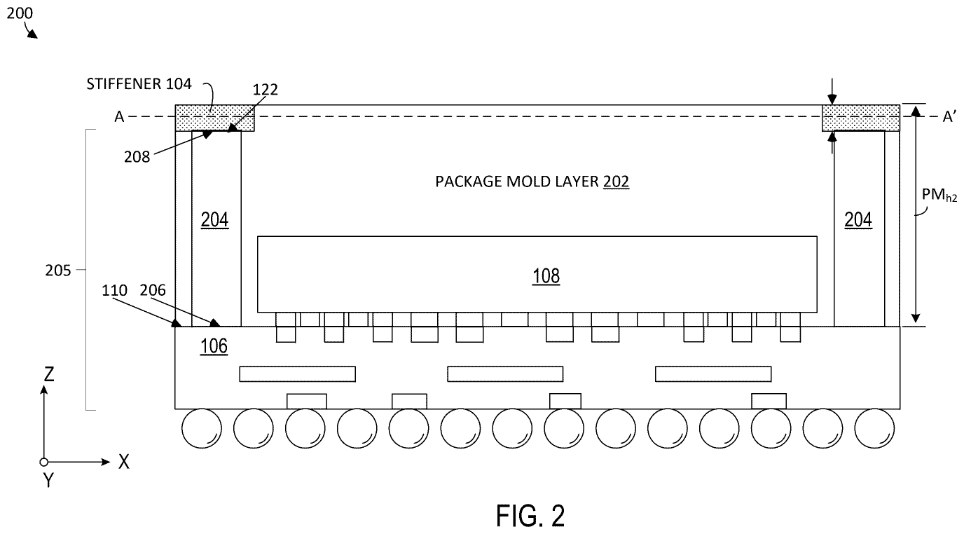

FIG. 2 is a side view of another exemplary IC package 200 that includes a package mold layer 202 and a stiffener 104 in the package mold layer 202 to reduce warpage. Common elements between the IC package 100 in FIG. 1 and the IC package 200 in FIG. 2 are shown with common element numbers.

The IC package 200 includes a die module 205. The die module 205 includes the substrate 106, the die 108, and passive devices 204. The passive devices 204 each have a first end 206 and a second end 208. The first end 206 is coupled to the top surface 110 of the substrate 106. The second end 208 is adjacent to the bottom surface 122 of the stiffener 104. In other words, the second end 208 is coincident with the bottom surface 122 of the stiffener 104. The package mold layer 202 has a height PMₕ₂ which is equal to the height PMₕ of the package mold layer 102. The stiffener 104 deployed in the IC package 200 reduces warpage that may be additionally increased by deploying the passive devices 204 on the substrate 106. The passive devices 204 may each be a surface mount package.

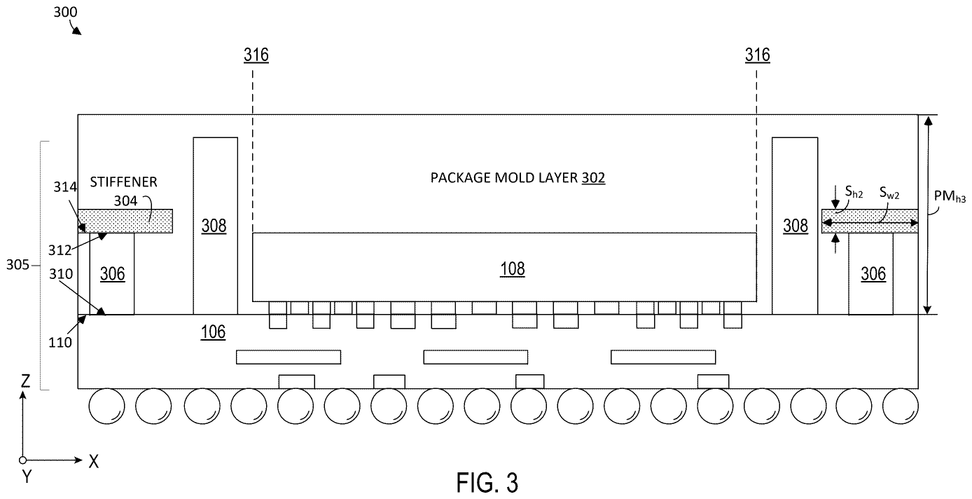

FIG. 3 is a side view of another exemplary IC package 300 that includes a package mold layer 302 and a stiffener 304 in the package mold layer 302 to reduce warpage. Common elements between the IC packages 100, 200 in FIGS. 1-2 and the IC package 300 in FIG. 3 are shown with common element numbers.

The IC package 300 includes a die module 305. The die module 305 includes the substrate 106, the die 108, and passive devices 306 and taller passive devices 308. The passive devices 306 are on the outside periphery of the taller passive devices 308. The passive devices 306 each have a first end 310 and a second end 312. The stiffener 304 has a bottom surface 314. The first end 310 is coupled to the top surface 110 of the substrate 106. The second end 312 is adjacent to the bottom surface 314 of the stiffener 304. In other words, the second end 312 is coincident with the bottom surface 314 of the stiffener 304. The package mold layer 302 has a height PMₕ₃ which is less than or equal to the height PMₕ of the package mold layer 102. The passive devices 306, 308 may each be a surface mount package.

The die 108 has a periphery 316. The stiffener 304 is outside the periphery 316 of the die 108. The stiffener 304 has a height Sₕ₂ of approximately 100 μm but can be in the range between 100-200 μm. The stiffener 304 has a width S_{w2} of approximately 500 μm but can be in the range between 500-1000 μm. Thus, the stiffener 304 has a ratio of width to height of 5 but can be in the range between 2.5-10. The stiffener 304 has a shape from a top view perspective of a hollow quadrangle as shown in FIG. 5A. The stiffener 304 deployed in the IC package 300 reduces warpage that may be additionally increased by deploying the passive devices 306, 308 on the substrate 106. At the same time, if the passive devices 308 have the same height as the passive devices 204, the overall IC package height can be reduced by the height of the stiffener 104 in FIG. 2.

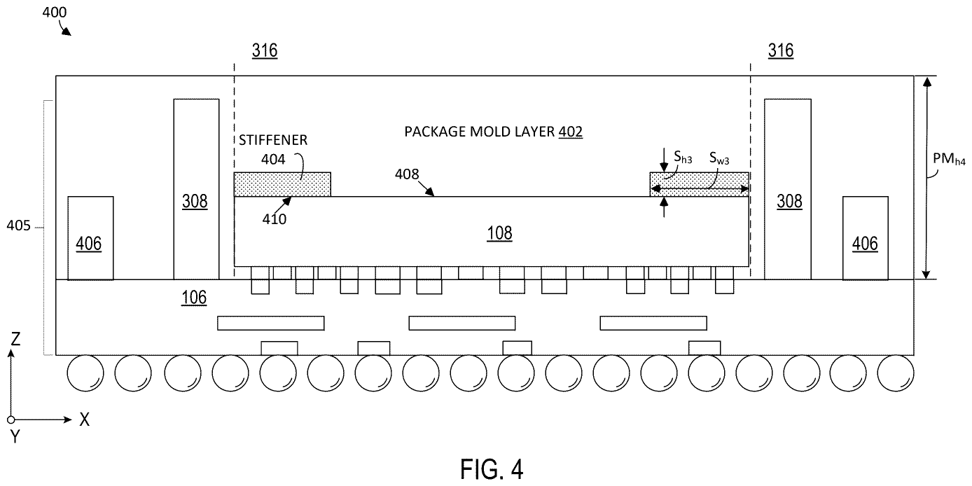

FIG. 4 is a side view of another exemplary IC package 400 that includes a package mold layer 402 and a stiffener 404 in the package mold layer 402 to reduce warpage. Common elements between the IC packages 100, 200, and 300 in FIGS. 1-3 and the IC package 400 in FIG. 4 are shown with common element numbers.

The IC package 400 includes a die module 405. The die module 405 includes the substrate 106, the die 108, and passive devices 406 and taller passive devices 308. The passive devices 406 are on the outside periphery of the taller passive devices 308. The passive devices 406 are coupled to the substrate 106 and may each be a surface mount package. The package mold layer 402 has a height PMₕ₄ which is less than or equal to the height PMₕ of the package mold layer 102.

The die 108 has a backside 408. The stiffener 404 is inside the periphery 316 of the die 108. The stiffener 404 includes a bottom surface 410. The stiffener 404 is adjacent to the backside 408 of the die 108. In other words, the bottom surface 410 of the stiffener 404 is coincident with the backside 408. The stiffener 404 has a height Sₕ₃ of approximately 100 μm but can be in the range between 100-200 μm. The stiffener 404 has a width S_{w3} of approximately 500 μm but can be in the range between 500-1000 μm. Thus, the stiffener 404 has a ratio of width to height of 5 but can be in the range between 2.5-10. The stiffener 404 has a shape from a top view perspective of a hollow quadrangle as shown in FIG. 5A. The stiffener 404 deployed in the IC package 400 reduces warpage that may be additionally increased by deploying the passive devices 406, 308 on the substrate 106. At the same time, if the passive devices 308 have the same height as the passive devices 204, the overall IC package height can be reduced by the height of the stiffener 104 in FIG. 2.

The stiffeners 104, 304, and 404 described in FIGS. 1-4 are composed primarily of copper (Cu) but may alternatively be composed of stainless steel. The stiffeners 104, 304, and 404 may have different shapes from a top view perspective. FIGS. 5A-5C illustrate different shapes of the stiffeners 104, 304, and 404 which are deployed in a package mold layer to reduce warpage in their respective IC package.

FIG. 5A is a top view of an exemplary stiffener 500 having a hollow quadrangle shape including, but not limited to, the stiffeners illustrated in FIGS. 1-4. The stiffener 500 has a height Sₕ (not shown). The length Eₗ of the quadrangle may be in the range between 10 millimeters (mm) and 25 μm. The ratio between S_{w} to Eₗ is in the range between 0.02 and 0.1 to advantageously prevent warpage. The stiffener 500 has the least amount of metal of the shapes disclosed in FIGS. 5A-5C.

FIG. 5B is a top view of another exemplary stiffener 502 having a rectangular grid shape including, but not limited to, the stiffeners illustrated in FIGS. 1-4. The length Eₗ of the quadrangle may be in the range between 10 mm and 25 mm. The ratio between S_{w} to Eₗ is in the range between 0.02 and 0.1 to advantageously prevent warpage on an IC package having a height in the range between 1 mm and 1.5 mm.

FIG. 5C is a top view of another exemplary stiffener 504 having a quadrangle with two cross members, each cross member attached to opposing corners of the quadrangle, the stiffener including, but not limited to, the stiffeners illustrated in FIGS. 1-4. The length Eₗ of the quadrangle may be in the range between 10 mm and 25 mm. The ratio between S_{w} to Eₗ is in the range between 0.02 and 0.1 to advantageously prevent warpage on an IC package having a height ranging between 1 mm and 1.5 mm.

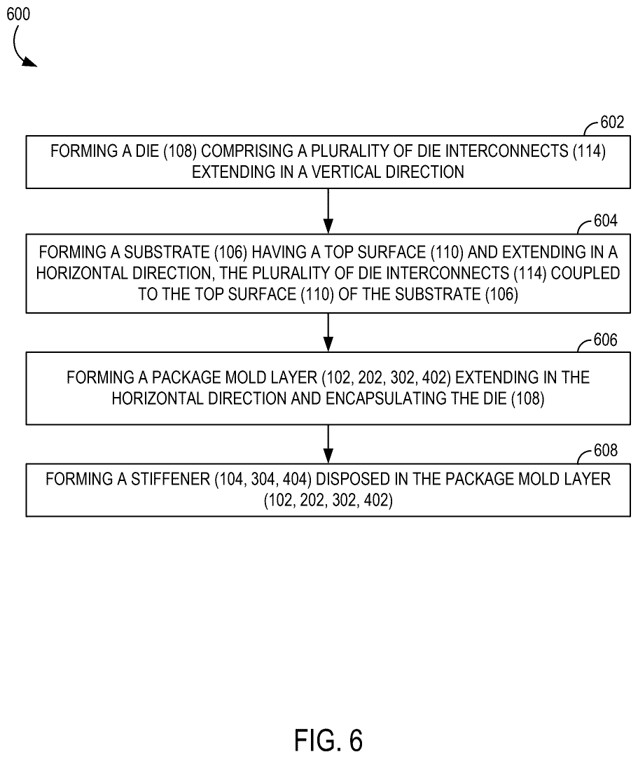

An electronic device including, but not limited to, an IC package, such as the IC packages 100, 200, 300, and 400, which includes a package mold layer and a stiffener in the package mold layer to reduce warpage and can be fabricated by different fabrication processes. FIG. 6 is a flowchart illustrating an exemplary fabrication process of fabricating an IC package including, but not limited to, the IC packages described in FIGS. 1-4, wherein the IC package includes a package mold layer and a stiffener in the package mold layer to reduce warpage. In this regard, a first exemplary step of fabricating the IC package can include forming a die 108 comprising a plurality of die interconnects 114 extending in a vertical direction (block 602 in FIG. 6). The next step in the fabrication process 600 can include forming a substrate 106 having a top surface 110 and extending in a horizontal direction, the plurality of die interconnects 114 coupled to the top surface 110 of the substrate 106 (block 604 in FIG. 6). The next step in the fabrication process 600 can include forming a package mold layer 102, 202, 302, 402 extending in the horizontal direction and encapsulating the die 108 (block 606 in FIG. 6). The next step in the fabrication process 600 can include forming a stiffener 104, 304, 404 disposed in the package mold layer 102, 202, 302, 402 (block 608 in FIG. 6).

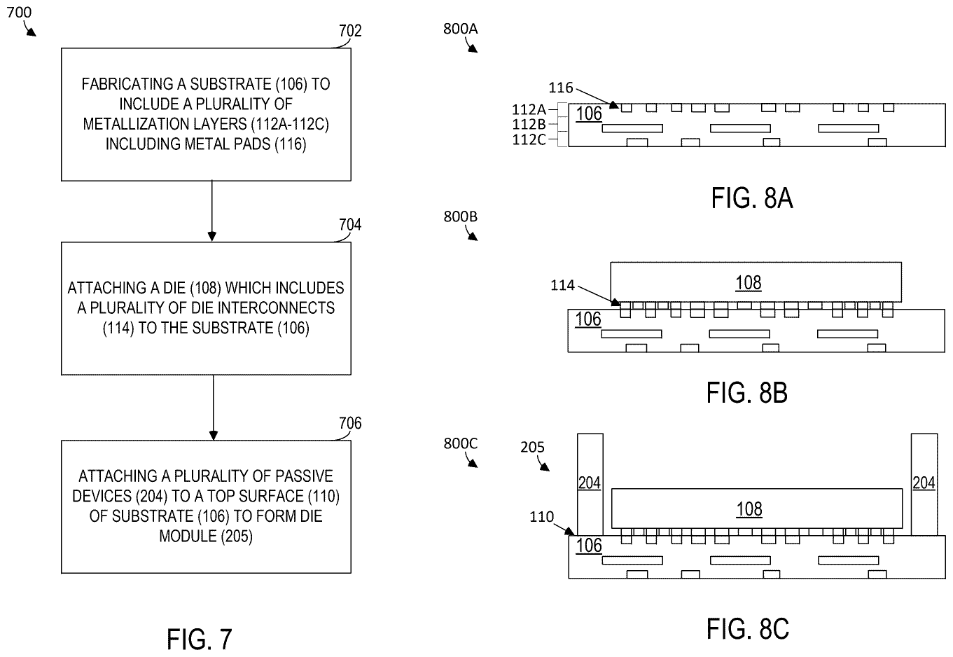

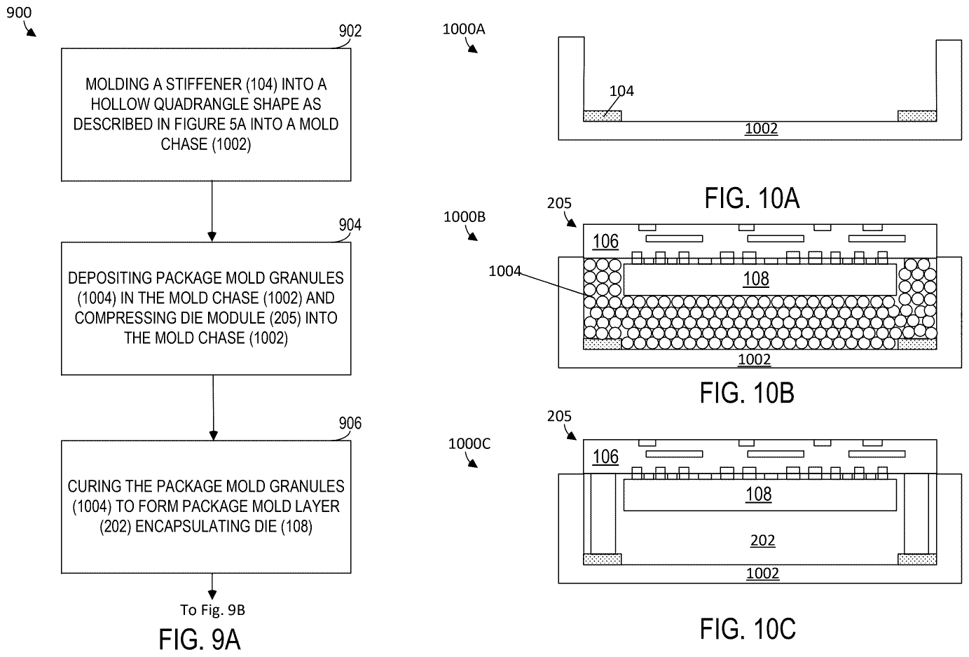

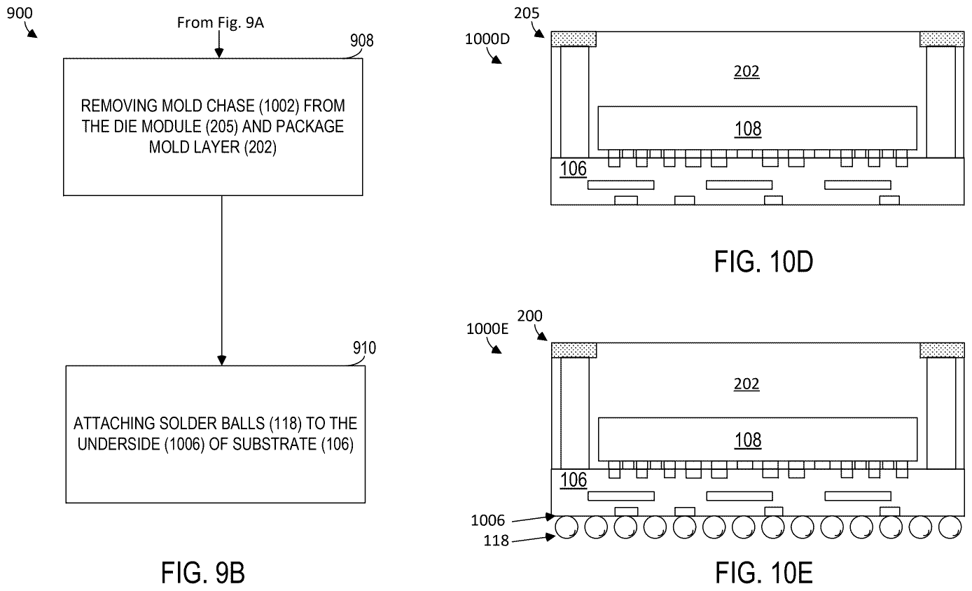

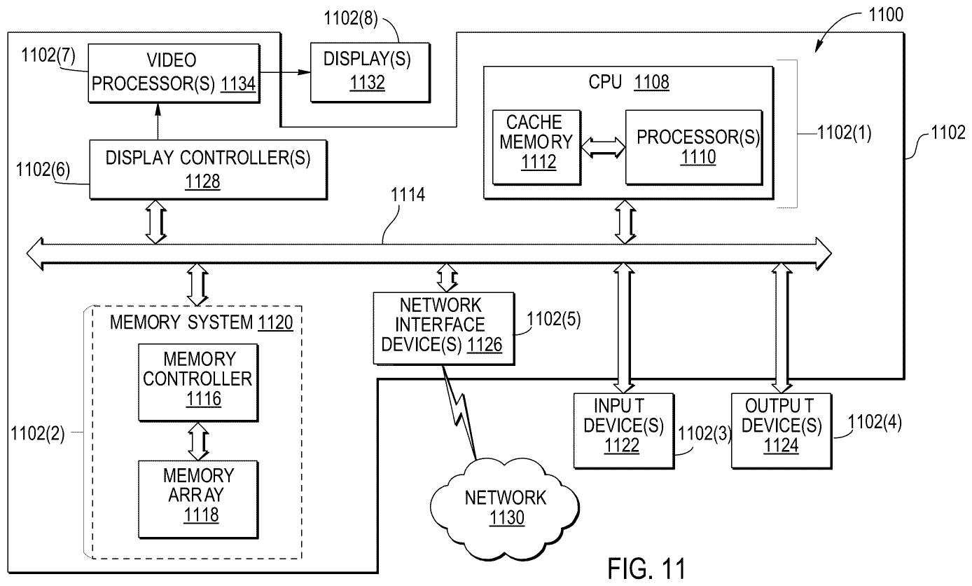

Other fabrication processes can also be employed to fabricate an IC package including, but not limited to, the IC packages FIGS. 1-4, wherein the IC package includes a package mold layer and a stiffener in the package mold layer to reduce warpage. To this end, FIGS. 7 and 8A-8C describe fabricating a die module, such as the die modules 105, 205, 305, and 405, and FIGS. 9A-9B and 10A-10E describe fabricating an IC package including, but not limited to, the IC packages FIGS. 1-4, wherein the IC package includes a package mold layer and a stiffener in the package mold layer to reduce warpage utilizing the die module fabricated in FIGS. 7 and 8A-8C. For convenience, the fabrication process 700 will be described in connection with the die module 205 as shown in FIG. 2, and the fabrication process 900 will be described in connection with the die module 205 and the IC package 200 but is also applicable to the IC packages 100, 300, and 400.

In this regard, FIG. 7 is a flowchart illustrating an exemplary fabrication process 700 of fabricating a die module including, but not limited to, the die modules in the IC packages described in FIGS. 1-4, wherein the die module will be fabricated in an IC package including a package mold layer and a stiffener in the package mold layer to reduce warpage. FIGS. 8A-8C are exemplary fabrication stages during fabrication of the die module according to the fabrication process 700 in FIG. 7.

As shown in fabrication stage 800A in FIG. 8A, a first exemplary step in the fabrication process 700 can include fabricating a substrate 106 to include a plurality of metallization layers 112A-112C including metal pads 116 (block 702 in FIG. 7). As shown at fabrication stage 800B in FIG. 8B, a next step in the fabrication process 700 can include attaching a die 108 which includes a plurality of die interconnects 114 to the substrate 106 (block 704 in FIG. 7). As shown at fabrication stage 800C in FIG. 8C, a next step in the fabrication process 700 can include attaching a plurality of passive devices 204 to a top surface 110 of the substrate 106 to form the die module 205 (block 706 in FIG. 7).

FIGS. 9A-9B is a flowchart illustrating an exemplary fabrication process 900 of fabricating an IC package including, but not limited to, the IC packages described in FIGS. 1-4, wherein the IC package includes a package mold layer and a stiffener in the package mold layer to reduce warpage. FIGS. 10A-10E are exemplary fabrication stages during fabrication of the IC package according to the fabrication process 900 in FIGS. 9A-9B.

In this regard, as shown in fabrication stage 1000A in FIG. 10A, an exemplary first step in the fabrication process 900 can include molding a stiffener 104 into a hollow quadrangle shape as described in FIG. 5A into a mold chase 1002 (block 902 in FIG. 9A). As shown in fabrication stage 1000B in FIG. 10B, a next step in the fabrication process 900 can include depositing package mold granules 1004 in the mold chase 1002 and compressing the die module 205 into the mold chase 1002 (block 904 in FIG. 9A). As shown in fabrication stage 1000C in FIG. 10C, a next step in the fabrication process 900 can include curing the package mold granules 1004 to form the package mold layer 202 encapsulating the die 108 (block 906 in FIG. 9A). As shown in fabrication stage 1000D in FIG. 10D, a next step in the fabrication process 900 can include removing the mold chase 1002 from the die module 205 and the package mold layer 202 (block 908 in FIG. 9B). As shown in fabrication stage 1000E in FIG. 10E, a next step in the fabrication process 900 can include attaching solder balls 118 to an underside 1006 of the substrate 106 (block 910 in FIG. 9B). If the IC package 200 is fabricated as part of a wafer level packaging process, the IC package 200 will also be singulated from the wafer in which it was manufactured.

Electronic devices that include an IC package, wherein the IC package is fabricated according to the fabrication processes in FIGS. 6, 7, and 9A-9B, wherein the IC package including, but not limited to, the IC packages described in FIGS. 1-4 includes a package mold layer and a stiffener in the package mold layer to reduce warpage, and according to any aspects disclosed herein, may be provided in or integrated into any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, laptop computer, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, an avionics system, and a multicopter.

In this regard, FIG. 11 is a block diagram of an exemplary processor-based system 1100 that can include an IC package including a package mold layer and a stiffener in the package mold layer to reduce warpage, including, but not limited to, the IC packages in FIGS. 1-4, and fabricated according to the fabrication processes in FIGS. 6, 7, and 9A-9B, and according to any exemplary aspects disclosed herein. In this example, the processor-based system 1100 may be assembled into one electronic device 1102 and in the form of an IC package(s) such as the IC packages 100, 200, 300, and 400 including a package mold layer and a stiffener in the package mold layer to reduce warpage. The processor-based system 1100 includes a central processing unit (CPU) 1108 that includes one or more processors 1110, which may also be referred to as CPU cores or processor cores. The CPU 1108 may have cache memory 1112 coupled to the CPU 1108 for rapid access to temporarily stored data. The CPU 1108 may be part of the electronic device 1102 or may be a different electronic device 1102(1). The CPU 1108 is coupled to a system bus 1114 and can intercouple client and server devices included in the processor-based system 1100. As is well known, the CPU 1108 communicates with these other devices by exchanging address, control, and data information over the system bus 1114. For example, the CPU 1108 can communicate bus transaction requests to a memory controller 1116, as an example of a controlled device. Although not illustrated in FIG. 11, multiple system buses 1114 could be provided, wherein each system bus 1114 constitutes a different fabric.

Other client and server devices can be connected to the system bus 1114. As illustrated in FIG. 11, these devices can include a memory system 1120 that includes the memory controller 1116 and a memory array(s) 1118, one or more input devices 1122, one or more output devices 1124, one or more network interface devices 1126, and one or more display controllers 1128, as examples. Each of the memory system(s) 1120, the one or more input devices 1122, the one or more output devices 1124, the one or more network interface devices 1126, and the one or more display controllers 1128 can be provided in the same electronic device 1102 or different electronic devices 1102(2)-1102(8). The input device(s) 1122 can include any type of input device, including, but not limited to, input keys, switches, voice processors, etc. The output device(s) 1124 can include any type of output device, including, but not limited to, audio, video, other visual indicators, etc. The network interface device(s) 1126 can be any device configured to allow exchange of data to and from a network 1130. The network 1130 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 1126 can be configured to support any type of communications protocol desired.

The CPU 1108 may also be configured to access the display controller(s) 1128 over the system bus 1114 to control information sent to one or more displays 1132. The display controller(s) 1128 sends information to the display(s) 1132 to be displayed via one or more video processor(s) 1134, which process the information to be displayed into a format suitable for the display(s) 1132. The display controller(s) 1128 and video processor(s) 1134 can be included as ICs in the same electronic device 1102 or different electronic devices 1102(6)-1102(8), and in the same or different electronic devices containing the CPU 1108, as an example. The display(s) 1132 can be provided as an electronic device 1102(8) and can include any type of display, including, but not limited to, a cathode ray tube (CRT), a liquid crystal display (LCD), a plasma display, a light emitting diode (LED) display, etc.

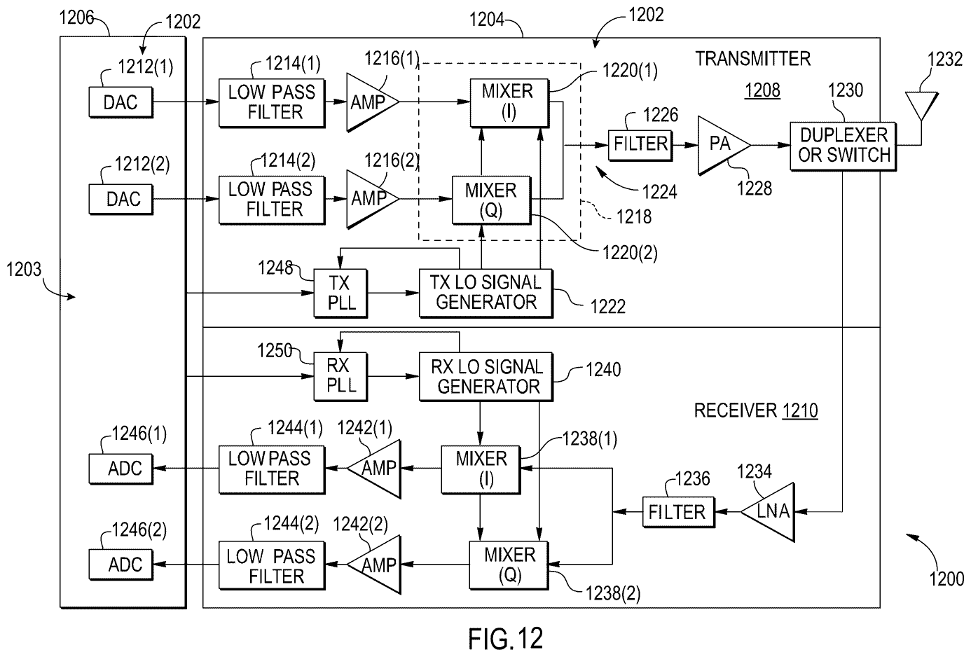

FIG. 12 is a block diagram of an exemplary wireless communications device 1200 that includes radio-frequency (RF) components that can include an IC package including a package mold layer and a stiffener in the package mold layer to reduce warpage, including, but not limited to, the IC packages in FIGS. 1-4, and fabricated according to the fabrication processes in FIGS. 6, 7, and 9A-9B, and according to any exemplary aspects disclosed herein. The wireless communications device 1200 may include or be provided in any of the above-referenced devices, as examples. As shown in FIG. 12, the wireless communications device 1200 includes a transceiver 1204 and a data processor 1206. The data processor 1206 may include a memory to store data and program codes. The transceiver 1204 includes a transmitter 1208 and a receiver 1210 that support bi-directional communications. In general, the wireless communications device 1200 may include any number of transmitters 1208 and/or receivers 1210 for any number of communication systems and frequency bands. All or a portion of the transceiver 1204 may be implemented on one or more analog ICs, RF ICs (RFICs), mixed-signal ICs, etc.

The transmitter 1208 or the receiver 1210 may be implemented with a super-heterodyne architecture or a direct-conversion architecture. In the super-heterodyne architecture, a signal is frequency-converted between RF and baseband in multiple stages, for example, from RF to an intermediate frequency (IF) in one stage, and then from IF to baseband in another stage for the receiver 1210. In the direct-conversion architecture, a signal is frequency-converted between RF and baseband in one stage. The super-heterodyne and direct-conversion architectures may use different circuit blocks and/or have different requirements. In the wireless communications device 1200 in FIG. 12, the transmitter 1208 and the receiver 1210 are implemented with the direct-conversion architecture.

In the transmit path, the data processor 1206 processes data to be transmitted and provides I and Q analog output signals to the transmitter 1208. In the exemplary wireless communications device 1200, the data processor 1206 includes digital-to-analog converters (DACs) 1212(1), 1212(2) for converting digital signals generated by the data processor 1206 into the I and Q analog output signals (e.g., I and Q output currents) for further processing.

Within the transmitter 1208, lowpass filters 1214(1), 1214(2) filter the I and Q analog output signals, respectively, to remove undesired signals caused by the prior digital-to-analog conversion. Amplifiers (AMPs) 1216(1), 1216(2) amplify the signals from the lowpass filters 1214(1), 1214(2), respectively, and provide I and Q baseband signals. An upconverter 1218 upconverts the I and Q baseband signals with I and Q transmit (TX) local oscillator (LO) signals through mixers 1220(1), 1220(2) from a TX LO signal generator 1222 to provide an upconverted signal 1224. A filter 1226 filters the upconverted signal 1224 to remove undesired signals caused by the frequency up-conversion as well as noise in a receive frequency band. A power amplifier (PA) 1228 amplifies the upconverted signal 1224 from the filter 1226 to obtain the desired output power level and provides a transmit RF signal. The transmit RF signal is routed through a duplexer or switch 1230 and transmitted via an antenna 1232.

In the receive path, the antenna 1232 receives signals transmitted by base stations and provides a received RF signal, which is routed through the duplexer or switch 1230 and provided to a low noise amplifier (LNA) 1234. The duplexer or switch 1230 is designed to operate with a specific receive (RX)-to-TX duplexer frequency separation, such that RX signals are isolated from TX signals. The received RF signal is amplified by the LNA 1234 and filtered by a filter 1236 to obtain a desired RF input signal. Down-conversion mixers 1238(1), 1238(2) mix the output of the filter 1236 with I and Q RX LO signals (i.e., LO_I and LO_Q) from an RX LO signal generator 1240 to generate I and Q baseband signals. The I and Q baseband signals are amplified by AMPs 1242(1), 1242(2) and further filtered by lowpass filters 1244(1), 1244(2) to obtain I and Q analog input signals, which are provided to the data processor 1206. In this example, the data processor 1206 includes analog-to-digital converters (ADCs) 1246(1), 1246(2) for converting the analog input signals into digital signals to be further processed by the data processor 1206.

In the wireless communications device 1200 of FIG. 12, the TX LO signal generator 1222 generates the I and Q TX LO signals used for frequency up-conversion, while the RX LO signal generator 1240 generates the I and Q RX LO signals used for frequency down-conversion. Each LO signal is a periodic signal with a particular fundamental frequency. A TX phase-locked loop (PLL) circuit 1248 receives timing information from the data processor 1206 and generates a control signal used to adjust the frequency and/or phase of the TX LO signals from the TX LO signal generator 1222. Similarly, an RX PLL circuit 1250 receives timing information from the data processor 1206 and generates a control signal used to adjust the frequency and/or phase of the RX LO signals from the RX LO signal generator 1240.

Those of skill in the art will further appreciate that the various illustrative logical blocks, modules, circuits, and algorithms described in connection with the aspects disclosed herein may be implemented as electronic hardware, instructions stored in memory or in another computer readable medium wherein any such instructions are executed by a processor or other processing device, or combinations of both. The devices and components described herein may be employed in any circuit, hardware component, integrated circuit (IC), or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein, but is to be accorded the widest scope consistent with the principles and novel features disclosed herein.

Implementation examples are described in the following numbered clauses:
1. An integrated circuit (IC) package, comprising:
   a die comprising a plurality of die interconnects;
   a substrate having a top surface and extending in a horizontal direction, the plurality of die interconnects coupled to the top surface of the substrate;
   a package mold layer extending in the horizontal direction and encapsulating the die; and
   a stiffener disposed in the package mold layer.
2. The IC package of clause 1, further comprising:
   a passive device having a first end and a second end, the first end coupled to the top surface of the substrate, the second end adjacent to the stiffener.
3. The IC package of clause 2, wherein the passive device is one of a plurality of passive devices coupled to the top surface of the substrate, the passive device having a height which is taller in a vertical direction of the plurality of passive devices.
4. The IC package of any of clauses 1-3, wherein the stiffener has a stiffener height in a vertical direction of approximately 100 micrometers (μm).
5. The IC package of any of clauses 1-4, wherein:
   the stiffener has a stiffener height in a vertical direction; and
   the stiffener has a width in the horizontal direction whose ratio of width to height is in the range between 2.5-10.
6. The IC package of any of clauses 1-5, wherein the stiffener has a shape of a hollow quadrangle.
7. The IC package of any of clauses 1-6, wherein the stiffener has a rectangular grid shape.
8. The IC package of any of clauses 1-7, wherein the stiffener has a quadrangle shape having two cross members, each cross member attached to opposing corners of the quadrangle shape.
9. The IC package of any of clauses 1-8, wherein the die has a periphery on the substrate, the stiffener being located within the periphery of the die.
10. The IC package of any of clauses 1-9, wherein the die has a periphery on the substrate, the stiffener being located outside the periphery of the die.
11. The IC package of any of clauses 1-10, wherein the stiffener is comprised of copper.
12. The IC package of any of clauses 1 -11 integrated into a device selected from a group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; an avionics systems; and a multicopter.
13. A method of fabricating an integrated circuit (IC) package, comprising:
   forming a die comprising a plurality of die interconnects extending in a vertical direction;
   forming a substrate having a top surface and extending in a horizontal direction, the plurality of die interconnects coupled to the top surface of the substrate;
   forming a package mold layer extending in the horizontal direction and encapsulating the die; and
   forming a stiffener disposed in the package mold layer.
14. The method of clause 13, further comprising:
   forming a passive device having a first end and a second end, the first end coupled to the top surface of the substrate, the second end adjacent to the stiffener.
15. The method of clause 14, wherein the passive device is one of a plurality of passive devices coupled to the top surface of the substrate, the passive device having a height which is taller in the vertical direction of the plurality of passive devices.
16. The method of any of clauses 13-15, wherein the stiffener has a stiffener height in the vertical direction of approximately 100 micrometers (μm).
17. The method of any of clauses 13-16, wherein:
   the stiffener has a stiffener height in the vertical direction; and
   the stiffener has a width in the horizontal direction whose ratio of width to height is in the range between 2.5-10.
18. The method of any of clauses 13-17, wherein forming the stiffener further comprises forming the stiffener into a hollow quadrangle shape.
19. The method of any of clauses 13-18, wherein forming the stiffener further comprises forming the stiffener into a rectangular grid shape.
20. The method of any of clauses 13-19, wherein forming the stiffener further comprises forming the stiffener into a quadrangle shape having two cross members, each cross member attached to opposing corners of the quadrangle shape.

What is claimed is:

1. An integrated circuit (IC) package, comprising:
a die comprising a plurality of die interconnects;
a substrate having a top surface and extending in a horizontal direction, the plurality of die interconnects coupled to the top surface of the substrate;
a package mold layer extending in the horizontal direction and encapsulating the die; and
a stiffener disposed in the package mold layer.

2. The IC package of claim 1, further comprising:
a passive device having a first end and a second end, the first end coupled to the top surface of the substrate, the second end adjacent to the stiffener.

3. The IC package of claim 2, wherein the passive device is one of a plurality of passive devices coupled to the top surface of the substrate, the passive device having a height which is taller in a vertical direction of the plurality of passive devices.

4. The IC package of claim 1, wherein the stiffener has a stiffener height in a vertical direction of approximately 100 micrometers (μm).

5. The IC package of claim 1, wherein:
the stiffener has a stiffener height in a vertical direction; and
the stiffener has a width in the horizontal direction whose ratio of width to height is in the range between 2.5-10.

6. The IC package of claim 1, wherein the stiffener has a shape of a hollow quadrangle.

7. The IC package of claim 1, wherein the stiffener has a rectangular grid shape.

8. The IC package of claim 1, wherein the stiffener has a quadrangle shape having two cross members, each cross member attached to opposing corners of the quadrangle shape.

9. The IC package of claim 1, wherein the die has a periphery on the substrate, the stiffener being located within the periphery of the die.

10. The IC package of claim 1, wherein the die has a periphery on the substrate, the stiffener being located outside the periphery of the die.

11. The IC package of claim 1, wherein the stiffener is comprised of copper.

12. The IC package of claim 1 integrated into a device selected from a group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; an avionics systems; and a multicopter.

13. A method of fabricating an integrated circuit (IC) package, comprising:
forming a die comprising a plurality of die interconnects extending in a vertical direction;
forming a substrate having a top surface and extending in a horizontal direction, the plurality of die interconnects coupled to the top surface of the substrate;
forming a package mold layer extending in the horizontal direction and encapsulating the die; and
forming a stiffener disposed in the package mold layer.

14. The method of claim 13, further comprising:
forming a passive device having a first end and a second end, the first end coupled to the top surface of the substrate, the second end adjacent to the stiffener.

15. The method of claim 14, wherein the passive device is one of a plurality of passive devices coupled to the top surface of the substrate, the passive device having a height which is taller in the vertical direction of the plurality of passive devices.

16. The method of claim 13, wherein the stiffener has a stiffener height in the vertical direction of approximately 100 micrometers (μm).

17. The method of claim 13, wherein:
the stiffener has a stiffener height in the vertical direction; and
the stiffener has a width in the horizontal direction whose ratio of width to height is in the range between 2.5-10.

18. The method of claim 13, wherein forming the stiffener further comprises forming the stiffener into a hollow quadrangle shape.

19. The method of claim 13, wherein forming the stiffener further comprises forming the stiffener into a rectangular grid shape.

20. The method of claim 13, wherein forming the stiffener further comprises forming the stiffener into a quadrangle shape having two cross members, each cross member attached to opposing corners of the quadrangle shape.
